(19) United States
(12) Patent Application Publication
(10) Pub. No.: US 2013/0159798 A1
(43) Pub. Date: Jun. 20, 2013

(54) NON-VOLATILE MEMORY DEVICE AND OPERATING METHOD THEREOF

(71) Applicant: Hea Jong YANG, Seoul (KR)

(72) Inventor: Hea Jong YANG, Seoul (KR)

(73) Assignee: SK hynix Inc., Icheon-si Gyeonggi-do (KR)

(21) Appl. No.: 13/601,366

(22) Filed: Aug. 31, 2012

(30) Foreign Application Priority Data
Dec. 20, 2011 (KR) 10-2011-0138202

(51) Int. Cl. G11C 29/08; G06F 11/26

(52) U.S. Cl. 714/721; 714/E11.159

(57) ABSTRACT

A non-volatile memory device and an operating method thereof are provided. The non-volatile memory device includes a memory unit including a plurality of memory blocks and a cam block, a peripheral circuit unit configured to program memory cells included in the plurality of memory blocks and the cam block or read programmed data, and a processor configured to control the peripheral circuit unit to measure an offset voltage by memory cell group in the plurality of memory blocks to set a read voltage during a test read operation and control the peripheral circuit unit to perform a read operation by memory cell group by using a new read voltage during a read operation.

### CROSS-REFERENCE TO RELATED APPLICATION

Priority is claimed to Korean patent application number 10-2011-0138202 filed on Dec. 20, 2011, the entire disclosure of which is incorporated herein by reference in its entirety.

### BACKGROUND

1. Technical Field

Various embodiments relate generally to a non-volatile memory device and an operating method thereof, and to a non-volatile memory device capable of improving reliability of data read during a read operation, and an operating method thereof.

2. Related Art

Demand for a non-volatile memory device available for electrical programming and erasing, while not requiring a refresh function such as rewriting data periodically, is increasing. Here, programming refers to an operation of writing data in a memory cell. Among non-volatile memory devices is a NAND type flash memory device in which a plurality of memory cells, adjacent cells sharing a drain and a source, are connected in series to configure a single cell string, having an advantage that it fits for storing large information.

A read operation of a non-volatile memory device is performed such that a read voltage is applied to a selected word line of a memory cell block, and sequentially, a potential of a bit line of a memory cell block is sensed. Namely, when a threshold voltage of the memory cell is lower than the read voltage, the potential of the bit line is discharged from a high voltage level to a low voltage level, and when the threshold voltage of the memory cell is higher than the read voltage, the potential of the bit line is maintained at the high voltage level, so the read operation is performed in the manner of sensing the potential maintained at the high voltage level.

When the threshold voltage of the memory cell is distributed in a negative region, it may be read according to the following two methods.

A first method is applying a negative verification voltage to the word line of the memory cell and sequentially sensing a potential of the bit line. This read method, however, has a problem in that a chip size is increased due to a high voltage transistor disposed to apply a negative voltage to the word line.

A second method is applying a voltage raised by a core voltage from a pass voltage to the other remaining word lines, excluding the selected word line, further raising a precharge level of a selected bit line by the core voltage than that of a related art, applying the core voltage to an unelected bit line, and applying the core voltage to a P well of a memory block to perform a read operation. As a result, although the threshold voltage of the selected memory cell is within the negative region, the threshold voltage is raised and read during a read operation, obtaining the same read data as that obtained by applying a negative read voltage to the selected word line.

However, in the second read method, the threshold voltage is required to be raised by the core voltage so as to be sensed during the read operation, but the raised threshold voltage value is changed due to resistance of a source line, a program state of memory cells adjacent to the selected memory cell, a position of a word line in a memory block, whether or not every page of a memory block has been programmed, and the like.

### BRIEF SUMMARY

Various embodiments generally relate to a non-volatile memory device in which an offset voltage is set for each memory cell group of a memory block to set a new read voltage by memory cell groups, thus improving accuracy in a read operation, and an operating method thereof.

A non-volatile memory device according to an embodiment includes: a memory unit including a plurality of memory blocks and a cam block; a peripheral circuit unit configured to perform a test read operation and a read operation on memory cells included in the plurality of memory blocks and the cam block; and a processor configured to control the peripheral circuit unit to perform the test read operation to measure an offset voltage by memory cell group of a plurality of memory blocks to set a new read voltage, and control the peripheral circuit unit to perform the read operation by memory cell group by using the new read voltage.

An operating method of a non-volatile memory device according to an embodiment includes: performing a test read operation using a virtual negative read (VNR) scheme on a memory cell block defined to include a plurality of memory cell groups; setting an offset voltage by comparing an actually raised threshold voltage value of each memory cell group measured according to the result of the test read operation with a target threshold voltage value of each memory cell group intended to be raised according to the VNR scheme; and setting a new read voltage by adding the offset voltage to a read voltage used in the test read operation.

An operating method of a non-volatile memory device according to an embodiment includes: programming a memory block defined to include a plurality of memory cell groups; performing a test read operation using a virtual negative read (VNR) scheme on each memory cell group of the memory block; setting a difference value between a raised threshold voltage value of each memory cell group based on the VNR scheme according to a result of the test read operation and an actually raised threshold voltage value of each memory cell group, as an offset voltage; setting a new read voltage corresponding to each memory cell group by using an offset voltage set for each memory cell group according to the test read operation; and performing a read operation by memory cell group of the memory block by using the new read voltage.

### BRIEF DESCRIPTION OF THE DRAWINGS

FIG. 1 is a block diagram of a non-volatile memory device according to an embodiment;

FIG. 2 is a flow chart illustrating a method for setting a read voltage according to an embodiment;

FIG. 3 is a graph of threshold voltages for explaining the method for setting a read voltage according to an embodiment; and

FIG. 4 is a flow chart illustrating a read method according to an embodiment.

### DETAILED DESCRIPTION

Hereinafter, various embodiments of the present disclosure will be described with reference to the accompanying drawings. However, embodiments may be implemented in many different forms and should not be construed as being limited to the embodiments set forth herein. Rather, these embodiments are provided so that the disclosure will be thorough and complete, and will fully convey the scope of the invention to those skilled in the art.

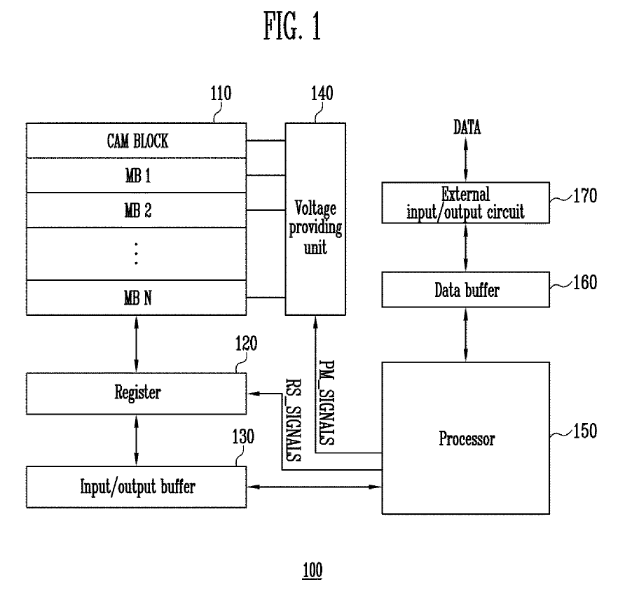

FIG. 1 is a block diagram of a non-volatile memory device according to an embodiment.

Referring to FIG. 1, a non-volatile memory device 100 may include a memory unit 110, a peripheral circuit unit, a processor 150, a data buffer 160, and an external input/output circuit 170. The memory unit 110 including a cam block and a plurality of memory blocks MB1 to MBN. The peripheral circuit unit may include a register 120, a input/output buffer 130 and a voltage providing unit 140.

The plurality of memory blocks MB1 to MBN of the memory unit 110 may store data input from the outside during a program operation. The cam block may store a read voltage, an offset voltage, a read voltage range, a core voltage, information regarding a program scheme of the plurality of memory blocks MB1 to MBN during a program operation, and the like.

The register 120 may temporarily store data to be programmed in the plurality of memory blocks MB1 to MBN or the cam block in response to control signals RS_SIGNALS output from the processor 150 during the program operation, and may sense a program state of the memory cells included in the plurality of memory blocks MB1 to MBN during an offset voltage setting operation.

The input/output buffer 130 may receive program data from the processor 150 during the program operation, and may output sensing data stored in the register 120 to the processor 150 during a read operation.

The voltage providing unit 140 may output a program voltage to a memory block selected from among the plurality of memory blocks MB1 to MBN in response to control signals PM_SIGNALS output from the processor 150 during the program operation, output a sequentially changing verification voltage to a memory block selected from among the plurality of memory blocks MB1 to MBN during a test read operation, and outputting a set read voltage to a memory block selected from among the plurality of memory blocks MB1 to MBN during a read operation. The processor 150 may control the register 120 and the voltage providing unit 140 to program program data in a memory block selected from among the plurality of memory blocks MB1 to MBN according to program data during the program operation.

During the test read operation, the processor 150 may control the register 120 to verify the memory cells included in the plurality of memory blocks MB1 to MBN, compare the number of fail bits as a result of the verification with the maximum allowable number of bits that may be processed by an error correction circuit (ECC), and subsequently set a read voltage range of each memory cell group of each memory block. Also, the processor 150 may compare an actually raised threshold voltage value of each memory cell group of each memory block with a core voltage to set an offset voltage.

During the read operation, the processor 150 may set a new read voltage by using the offset voltage and may control the register 120 and the voltage providing unit 140 to read data programmed in the plurality of memory blocks MB1 and MBN by using the set read voltage and the set read voltage range.

The data buffer 160 may output data input through the external input/output buffer 170 to the processor 150 during the program operation, or may receive read data from the processor 150 and may output the received read data to the external input/output buffer 170 during the read operation.

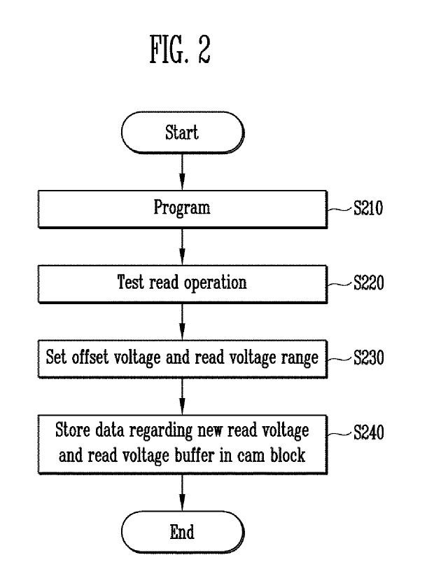

FIG. 2 is a flow chart illustrating a method for setting a read voltage according to an embodiment.

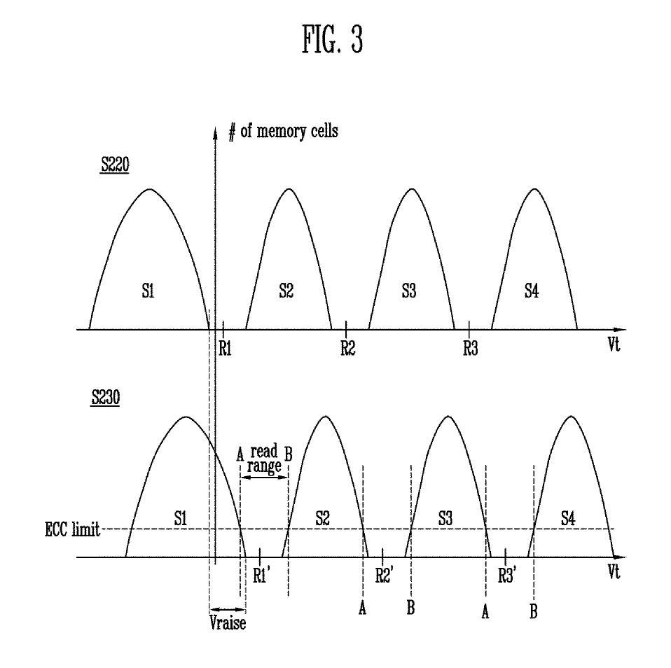

FIG. 3 is a graph of threshold voltages (i.e., Vt) verses the number or memory cells (i.e., # of memory cells) for illustrating the method for setting a read voltage according to an embodiment.

A method for setting a read voltage according to an embodiment will be described with reference to FIGS. 1 to 3.

1) Programming (S210) (i.e., Program)

Data DATA input from outside the non-volatile memory device 100 is transferred to the processor 150 through the external input/output circuit 170 and the data buffer 160. The processor 150 may scramble the input data to generate random data. Preferably, the random data is generated such that data ‘1’ and data ‘0’ are uniform.

The register 120 may receive the random data generated by the processor 150 through the input/output circuit 130 and may temporarily store the same. The register 120 may control potentials of the bit lines connected to the plurality of memory blocks MB1 to MBN according to the temporarily stored random data. Thereafter, in response to the control signals PM_SIGNALS output from the processor 150, the voltage providing unit 140 may apply a program voltage to a memory block selected from among the plurality of memory blocks MB1 to MBN to perform programming.

The foregoing program operation may be normal programming to program data in all the pages of the memory block or partial programming to program data in only some of the pages of the memory block.

2) Test Read Operation to Set a Read Voltage Range and Offset Voltage (S220) (i.e., Test Read Operation)

A test read operation may be performed. Here, preferably, a virtual negative read (VNR) scheme may be used as the test read operation. Also, a new pass voltage raised by a core voltage Vcore (e.g., 1V) from a pass voltage may be applied to the other remaining word lines, excluding a word line selected from the memory block selected from among the plurality of memory blocks MB1 to MBN, a precharge level of a selected bit line may be raised by the core voltage Vcore, the core voltage Vcore may be applied to an unselected bit line, and the core voltage Vcore may be applied to a P well of the selected memory block, to perform a read operation.

Accordingly, a threshold voltage value of the memory cells of the selected memory block may be read ideally as a value raised by the core voltage Vcore. Thus, the read voltage in use may be raised by the core voltage Vcore and applied.

The foregoing read operation based on the VNR scheme may be performed, and here, the read operation may be performed several times by gradually raising or lowering the read voltage to detect first and second read voltages A and B, respectively in the read operation in which the number of fail bits included in read data is equal to a maximum number of bits allowed for the ECC.

Also, the highest threshold voltage value of the memory cells in an erase state (S1) during the read operation may be measured to calculate how high the threshold voltage value of the memory cells has been raised in actuality. Here, the value may be calculated by comparing a maximum threshold voltage value of a memory cell block on which an erase operation was finished with the highest threshold voltage value of the memory cells in the erase state (S1) during the read operation. In general, the erase operation may include a hard erase operation and a soft program operation, and a maximum threshold voltage value of the memory cells in an erase state during the soft program operation may be set and soft-programmed, so the set value herein may be the maximum threshold voltage value of the memory cell block on which the erase operation was finished.

Preferably, the foregoing test read operation may be repeatedly executed with respect to all of first to third read operations to read first to fourth threshold voltage groups S1 to S4.

The foregoing test read operation may be executed based on the memory cells connected to the same word line, and here, in order to reduce an operational speed, the memory cells connected to a plurality of word lines may be defined as a single memory cell group and the test read operation may be performed on each memory cell group. For example, in the case of a memory block in which 64 word lines are connected, memory cells connected to first to sixteenth word lines may be defined as a first memory cell group, memory cells connected to seventeenth to thirty-second word lines may be defined as a second memory cell group, memory cells connected to thirty-three to forty-eighth word lines may be defined as a third memory cell group, and fourth-ninth to sixty-fourth word lines may be defined as a fourth memory cell group, and the forgoing test operation may then be performed on each group.

3) Setting Offset Voltage and Read Voltage Range (S230)

An offset voltage corresponding to each of the first to fourth memory cell groups may be set by using the actually raised memory threshold value Vraise obtained as a result of the foregoing test read operation. Preferably, the offset voltage Voffset is set as a difference value between a target threshold voltage value of the memory cell groups intended to be raised ideally during a read operation based on the VNR scheme and the actually raised threshold voltage value of the memory cells. Namely, the offset voltage Voffset is set as a difference value between the core voltage Vcore (not illustrated) and the actually raised threshold voltage value Vraise of the memory cells. For example, when the core voltage is 1V and the actually raised threshold voltage value of the memory cells is 0.9V, the offset voltage is −0.1V, and when the core voltage is 1V and the actually raised threshold voltage value is 1.1V, the offset voltage is 0.1V.

An interval from a first read voltage A to a second read voltage B obtained from each of the first to fourth memory groups according to the result of the foregoing test read operation is set as a read voltage range (i.e., read range).

4) Storing Data With Respect to New Read Voltage and Read Interval in Cam Block (S240) (i.e., Store Data Regarding New Read Voltage and Read Voltage Buffer in Cam Block)

The data regarding the new read voltage and the read interval may be stored in the cam block of the memory unit 110. The new read voltage may be set as a read voltage corresponding to each memory cell group by using the offset voltage. Namely, new read voltages R1′, R2′, and R3′ may be set as values obtained by adding the offset read voltage Voffset to the read voltage R1, R2, R3 applied during the test read operation.

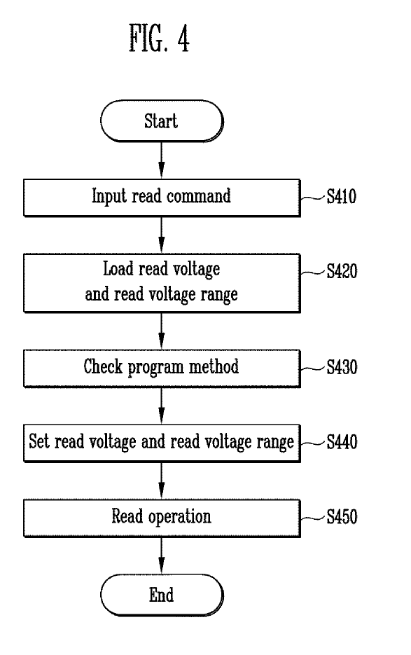

FIG. 4 is a flow chart illustrating a read operation according to an embodiment.

A read operation according to an embodiment will be described with reference to FIGS. 1 to 4.

1) Read Command Input (S410) (i.e., Input Read Command)

When a read command is input from the outside, the processor 150 may output control signals for controlling the register 120 and the voltage providing unit 140 according to an algorithm for performing a read operation.

2) Read Interval Loading (S420) (i.e., Load Read Voltage and Read Voltage Range)

The data regarding the new read voltages and the read intervals stored in the cam block may be read and temporarily stored in the register 120, and subsequently, the data may be transmitted to the processor 150.

3) Program Method Checking (S430) (i.e., Check Program Method)

The program method information stored in the cam block may be read, temporarily stored in the register 120, and subsequently, transmitted to the processor 150. The processor 150 may ascertain whether the memory cell blocks have been programmed according to the normal programming or the partial programming during a program operation by using the read data.

4) Setting Read Voltage and Read Interval (S440) (i.e., Set Read Voltage and Read Voltage Range)

The processor 150 may set a new read voltage and a new read interval by using the data read from the cam block.

5) Read Operation (S450)

In response to the control signals RS_SIGNALS and PM_SIGNALS output from the processor 150, the register 120 and the voltage providing unit 140 may read data programmed in the memory blocks MB1 to MBN, respectively. The read operation may be performed by using the read voltage and the read interval set for each memory cell group of each memory block. The read operation may be repeatedly performed by gradually raising or lowering the set read voltage to a value within the read interval. Also, the foregoing read operation may be performed based on the foregoing VNR scheme.

According to an embodiment as described above, since a read voltage and a read interval may be set for each memory cell group of each memory block, an optimized read operation can be performed.

As described above, offset voltages may be set by memory cell group of a memory block to set a new read voltage by memory cell groups, thereby improving accuracy of a read operation. Also, since an interval in which the number of fail bits is equal to a maximum allowable number of bits for an error correction circuit (ECC), reliability of read data can be improved.

It should be understood that the embodiments described herein should be considered in a descriptive sense only and not for purposes of limitation. Descriptions of features or aspects within each embodiment should typically be considered as available for other similar features or aspects in other embodiments.

What is claimed is:

1. A non-volatile memory device comprising:
a memory unit including a plurality of memory blocks and a cam block;
a peripheral circuit unit configured to perform a test read operation and a read operation on memory cells included in the plurality of memory blocks and the cam block; and
a processor configured to control the peripheral circuit unit to perform the test read operation to measure an offset voltage by memory cell group of a plurality of memory blocks to set a new read voltage, and control the peripheral circuit unit to perform the read operation by memory cell group by using the new read voltage.

2. The non-volatile memory device of claim 1, wherein the processor measures the offset voltage according to a highest threshold voltage value in a threshold voltage distribution of memory cells in an erase state by memory cell group programmed during the test read operation.

3. The non-volatile memory device of claim 1, wherein the processor sets the new read voltage used for the read operation by adding the offset voltage to a read voltage used for the test read operation.

4. The non-volatile memory device of claim 1, wherein the processor sets a range between read voltages from which a maximum allowable number of bits that can be processed by an error correction circuit during the test read operation, as a read voltage range.

5. The non-volatile memory device of claim 1, wherein the test read operation and the read operation use a virtual negative read (VNR) scheme.

6. The non-volatile memory device of claim 4, wherein during the test read operation, a read voltage at which the maximum allowable number of bits is detected by raising or lowering the read voltage based on the a reference read voltage.

7. The non-volatile memory device of claim 4, wherein the processor stores the offset voltage and the read voltage range in the cam block, and during the read operation, the processor reads the offset voltage and the read voltage range stored in the cam block to set the new read voltage.

8. An operating method of a non-volatile memory device, the method comprising:
performing a test read operation using a virtual negative read (VNR) scheme on a memory cell block defined to include a plurality of memory cell groups;
setting an offset voltage by comparing an actually raised threshold voltage value of each memory cell group measured according to the result of the test read operation with a target threshold voltage value of each memory cell group intended to be raised according to the VNR scheme; and
setting a new read voltage by adding the offset voltage to a read voltage used in the test read operation.

9. The method of claim 8, wherein the test read operation is performed by a memory cell group.

10. The method of claim 8, wherein, based on the VNR scheme, threshold voltage values of a plurality of memory cells included in the memory cell block are raised by a core voltage so as to be read.

11. The method of claim 8, wherein the test read operation comprises detecting a first read voltage and a second read voltage of a point from which the number of fail bits equal to a maximum allowable number of bits that are detected by gradually raising or lowering an applied read voltage.

12. The method of claim 11, further comprising:
setting an interval between the first read voltage and the second read voltage, as a read voltage range.

13. An operating method of a non-volatile memory device, the method comprising:
programming a memory block defined to include a plurality of memory cell groups;
performing a test read operation using a virtual negative read (VNR) scheme on each memory cell group of the memory block;
setting an offset voltage by comparing an actually raised threshold voltage value of each memory cell group measured according to the result of the test read operation with a target threshold voltage value of each memory cell group intended to be raised according to the VNR scheme;
setting a new read voltage corresponding to each memory cell group by using an offset voltage set by memory cell group according to the test read operation; and
performing a read operation by memory cell group of the memory block by using the new read voltage.

14. The operating method of claim 13, wherein the memory block is programmed according to a normal program scheme of programming data in all pages or a partial program scheme of programming data in only some of the pages.

15. The operating method of claim 13, wherein, during the test read operation, first and second read voltages at which a maximum allowable number of bits that can be processed by an error correction circuit are detected by raising or lowering a read voltage based on a reference read voltage.

16. The operating method of clam 15, wherein an interval between the first read voltage and the second read voltage is set as a read voltage range.

17. The operating method of claim 13, wherein the offset voltage is measured by using a highest threshold voltage value in a threshold voltage distribution of memory cells in an erase state by the memory cell group during the test read operation.

18. The operating method of claim 17, wherein, in setting a new read voltage, a new read voltage is set by adding the offset voltage to a read voltage used in the test read operation.
